(19) United States
(12) Patent Application Publication
(10) Pub. No.: US 2005/0139869 A1
(43) Pub. Date: Jun. 30, 2005

(54) Semiconductor device

(76) Inventors: Takahisa Akiba, Tsuruoka-shi (JP); Masahiko Tsuyuki, Chino-shi (JP); Kenji Yokoyama, Sakata-shi (JP)

Correspondence Address: HARNESS, DICKEY & PIERCE, P.L.C., P.O. BOX 828, BLOOMFIELD HILLS, MI, 48303, US

(21) Appl. No.: 11/022,068

(22) Filed: Dec. 23, 2004

(30) Foreign Application Priority Data
Dec. 25, 2003 (JP) 2003-429403

(51) Int. Cl. H01L 27/148

(52) U.S. Cl. 257/224

(57) ABSTRACT

A semiconductor device is provided including a gate insulation layer formed on a semiconductor substrate, a source and drain region, an offset region composed of a doped layer of which concentration is low comparing to that of the source region and drain region and surrounds the source region and drain region, and a channel stopper region formed on the outside of the offset region. The channel stopper region includes a protrusion toward the long side direction of the gate insulation layer such that the distance between the gate insulation layer and the channel stopper region is narrower than the distance between the offset region and the channel stopper region.

### RELATED APPLICATIONS

This application claims priority to Japanese Patent Application No. 2003-429403 filed Dec. 25, 2003 which is hereby expressly incorporated by reference herein in its entirety.

### BACKGROUND

1. Technical Field

The present invention relates to a semiconductor device including a high voltage transistor driven with high voltage. In particular, it relates a semiconductor device including a high voltage transistor of which characteristics and micro-miniaturization are improved.

2. Related Art

A high voltage transistor driven with high voltage needs the sufficient distance between an offset region and a channel stopper region to assure the high voltage proof FIG. 10 shows one of the conventional high voltage transistors that is explained hereafter. FIG. 10 is a plan view schematically showing the positional relationship between an offset region 150 and a channel stopper region 154 in the conventional high voltage transistor. As shown in FIG. 10, high voltage proof is assured due to the sufficient distance between the channel stopper region 154 and the offset region 150. Further, in order to reduce a leak current, the distance between the channel stopper region 154 and the channel region is narrowed sometime by enlarging the channel region comparing to the source region and the drain region (the source/drain region) 152.

However, enlarging the channel region comparing to the source/drain region 152 described above sometime faces insufficient micro-miniaturization of a transistor. On the other hand, if the size of the channel region is equalized to that of the source/drain region 154, withstanding voltage is insufficient even micro-miniaturization is attained. Further, if the distance between the channel stopper region 154 and the channel region is narrowed to reduce a leak current, withstanding voltage is lowered due to insufficient distance between the offset region 150 and the channel stopper region 154. Hence, improvements of a leak current, withstanding voltage and micro-miniaturization are desired in a high voltage transistor.

The present invention is to provide a semiconductor device including a high voltage transistor of which withstanding voltage and micro-miniaturization are improved.

### SUMMARY

A semiconductor device of the present invention comprises: a gate insulation layer formed on a semiconductor layer; a source and a drain region formed in the semiconductor layer; an offset region composed of a doped layer of which concentration is low comparing to that of the source region and the drain region and surrounds the source region and the drain region; and a channel stopper region formed on the outside of the offset region. The stopper region includes a protrusion such that the distance between the gate insulation layer and the channel stopper region to the long side of the gate insulation layer is narrower than the distance between the offset region and the channel stopper region to the long side of the offset region.

According to the present invention, the channel stopper region includes a protrusion so as to make the distance short between the gate insulation layer and the channel stopper region in a plan view. Namely, it includes a protrusion along the direction which makes the distance narrower between the channel region and the channel stopper region. This results in reducing a leak current. On the other hand, withstanding voltage can be assured in an area between offset region and the channel stopper region due to holding the desired distance. Namely, according to a semiconductor device of the present invention, both withstanding voltage and reducing a leak current can be improved as forming a partial protrusion so as to make only the distance narrower between the channel stopper region and the channel region. Further, a narrow area is formed so as to be partially protruded only in the region in which the distance to the channel stopper region is narrowed. Hence, there is no necessity of changing a semiconductor device as a whole. As the result, it can be provided a semiconductor device in which micro-miniaturization is realized in addition to the above advantage.

### BRIEF DESCRIPTION OF THE DRAWINGS

FIG. 1 is a cross sectional view schematically showing a semiconductor device of one embodiment according to the present invention.

FIG. 2A is a plan view schematically showing the positional relationship between a source/drain region and an offset region of the semiconductor device of the embodiment. FIG. 2B is a sectional view taken along line A-A in FIG. 2A.

FIG. 3 is a sectional view schematically showing a fabricating process of a semiconductor device of the embodiment.

FIG. 4 is a sectional view schematically showing a fabricating process of a semiconductor device of the embodiment.

FIG. 5 is a sectional view schematically showing a fabricating process of a semiconductor device of the embodiment.

FIG. 6 is a sectional view schematically showing a fabricating process of a semiconductor device of the embodiment.

FIG. 7 is a sectional view schematically showing a fabricating process of a semiconductor device of the embodiment.

FIG. 8 is a sectional view schematically showing a fabricating process of a semiconductor device of the embodiment.

FIG. 9 is a sectional view schematically showing a fabricating process of a semiconductor device of the embodiment.

FIG. 10 is a plan view schematically showing the positional relationship between a source/drain region and an offset region of the semiconductor device according to a conventional example.

### DETAILED DESCRIPTION

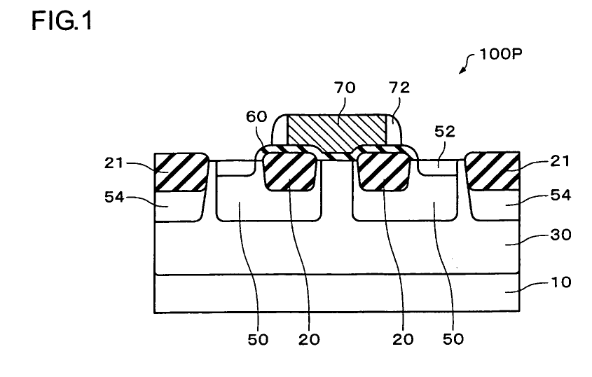

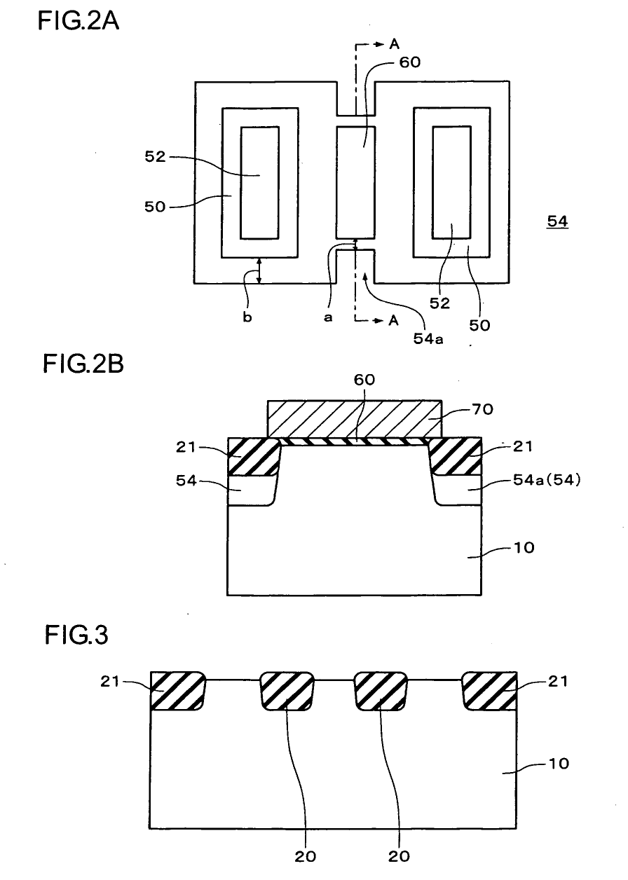

Embodiments of the invention will now be described with reference to FIGS. 1 and 2. FIG. 1 is a cross section schematically showing a semiconductor device of the embodiment. FIG. 2A is a plan view schematically showing the positional relationship between a source/drain region and a channel stopper region in the embodiment. FIG. 2B is a cross sectional view taken along the line A-A shown in FIG. 2A. In the embodiment, it will be explained an example in which P channel high voltage transistor 100P is formed on a semiconductor substrate 10. The example is for descriptive purpose and it can be surely applied to a semiconductor device of a hybrid structure including more than two different kinds of transistors.

According to a semiconductor device of the embodiment, as shown in FIG. 1, the P channel high voltage transistor 100P is formed in the region for forming a transistor which is partitioned by a element isolation insulation layer 21 fabricated in the semiconductor substrate 10. The element isolation insulation layer 21 is formed as a local oxidation of silicon (LOCOS) layer, a semi-recessed LOCOS layer and a shallow trench isolation (STI) layer.

The P channel high voltage transistor 100P comprises: a gate insulation layer 60, a gate electrode 70, a side wall insulation layer 72, an offset insulation layer 20, an offset region 50 composed of P-type low density doped region and a source/drain region 52 composed of P-type high density doped region.

The gate insulation layer 60 is formed on an N-type well 30 which will be a channel region. The gate electrode 70 is formed on the gate insulation layer 60. The offset insulation layer 20 is formed both sides of the gate insulation layer 60 under which the offset region 50 composed of P-type low density doped region is formed so as to surround the source/drain region 52.

The sidewall insulation layer 72 is formed to the side face of the gate electrode 70. The P-type high density doped region which will be the source/drain region 50 is formed outside the sidewall insulation layer 72.

A channel stopper region 54 is formed under an element isolation insulation layer 21 that is outside the offset region 50. The channel stopper region 54 is composed of N-type low density doped region.

FIG. 2A is a plan view schematically showing the position relationship among the source/drain region 52, the channel region, which is a semiconductor layer under the gate insulation layer 60, and the channel stopper region 54 in the semiconductor device of the embodiment. As shown in FIG. 2A, the channel stopper region 54 includes a protrusion 54a toward the long side of the gate insulation layer 60 in a plan view. That is, the protrusion 54a is included such that the distance “a” between the channel stopper region 54 and the channel region is narrower than the distance “b” between the channel stopper region 54 and the offset region 50.

In addition, as is shown in the sectional view of FIG. 2B, the protrusion 54a is formed so as to reach the end of the element isolation insulation layer 21 composed of a semi-recessed LOCOS layer.

According to the semiconductor device of the embodiment, the channel stopper region 54 includes the protrusion 54a toward the long side of the gate insulation layer 60 so as to make the distance narrow between the channel stopper region 54 and the gate isolation layer 60 (channel region) in a plan view. This results in reducing a leak current. On the other hand, withstanding voltage can be assured in the area between the offset region 50 and the channel stopper region 54 due to holding the desired distance. That is, according to the semiconductor device of the embodiment, both withstanding voltage and reducing the leak current can be improved as forming the channel stopper region 54 so as to partially be protruded in a plan view. Further, the semiconductor device includes a planar shape in which a protrusion is formed only in the region in which the distance to the channel stopper region is narrowed. Hence, there is no necessity of changing the semiconductor device as a whole. As the result, it can be provided a semiconductor device in which micro-miniaturization is further realized.

### Method Of Manufacturing A Semiconductor Device

A method of manufacturing a semiconductor device of the embodiment will be explained with reference to FIGS. 3 through 9. FIGS. 3 through 9 are sectional drawings schematically showing processes of a method of manufacturing a semiconductor device of the embodiment.

(1) As shown in FIG. 3, the offset insulation layer 20 for electric field relaxation and the element isolation insulation layer 21 to partition the region for forming a transistor. In the method of manufacturing the semiconductor device of the embodiment, it will be explained an example in which the offset insulation region 20 and the element isolation insulation layer 21 are formed by means of a semi-recessed LOCOS method.

Firstly, silicon oxynitride layer and silicon nitride layer playing a role of anti-oxidation film are deposited on the semiconductor substrate 10 in this order by means of a known technique with a CVD method. Then, a mask layer having an opening to a region where the offset insulation layer 20 and the element isolation insulation layer 21 are formed, is formed on the silicon nitride layer. Then, the silicon nitride layer, the silicon oxynitride layer and the semiconductor substrate are etched with the mask layer as a mask so as to form a trench to the semiconductor substrate. Subsequently, the offset insulation layer 20 and the element isolation insulation layer 21 composed of a semi-recessed LOCOS layer are formed by means of selective thermal oxidation method with the silicon nitride layer as anti-oxidation mask. Then, the silicon nitride layer is removed.

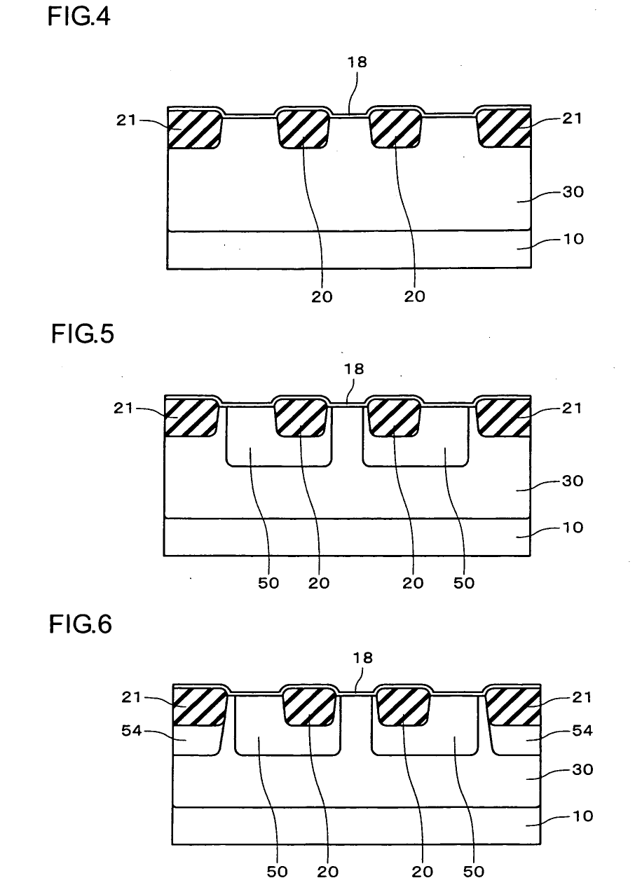

(2) Next, as shown in FIG. 4, the N-type well 30 is formed to the semiconductor substrate 10. In the forming of the N-type well 30, firstly, a sacrifice oxide film 18 is formed on the entire surface of the semiconductor substrate 10. For example, a silicon oxide film is formed as the sacrifice oxide film 18. Then, N-type impurities such like phosphorous, arsenic, or the like are implanted into the semiconductor substrate 10 at one time or several times and heat treatment is conducted to be diffused, if needed, so as to form the N-type well 30 in the semiconductor device 10.

(3) Next, as shown in FIG. 5, the offset region 50 composed of low density doped region is formed. In this process, the offset region 50 composed of low density doped region is formed by the following manner: a resist layer (not shown) is formed that includes an opening to the region in which the offset region 50 is formed; P-type impurities are implanted into the semiconductor substrate 10 with the resist layer as a mask; and heat treatment is conducted, if needed.

(4) As shown in FIG. 6, the channel stopper region 54 is formed under the element isolation insulation layer 21. In this process, firstly, the resist layer (not shown) is formed that includes an opening to the region in which the channel stopper region 54 is formed. Then, N-type impurities are implanted into the semiconductor substrate 10 with the resist layer as a mask and heat treatment is conducted, if needed, so as to form the channel stopper region 54. As referred to FIG. 2A, the resist layer includes an opening having the shape in which a protrusion is protruded toward the long side of the gate insulation layer 6 in a plan view. Subsequently, the sacrifice oxide layer 18 can be removed by means of wet etching with, for example, dilute hydrofluoric acid.

In addition, the heat treatment is conducted, if needed, in the above-mentioned processes (3) and (4) may be conducted in the same process, not in individual process.

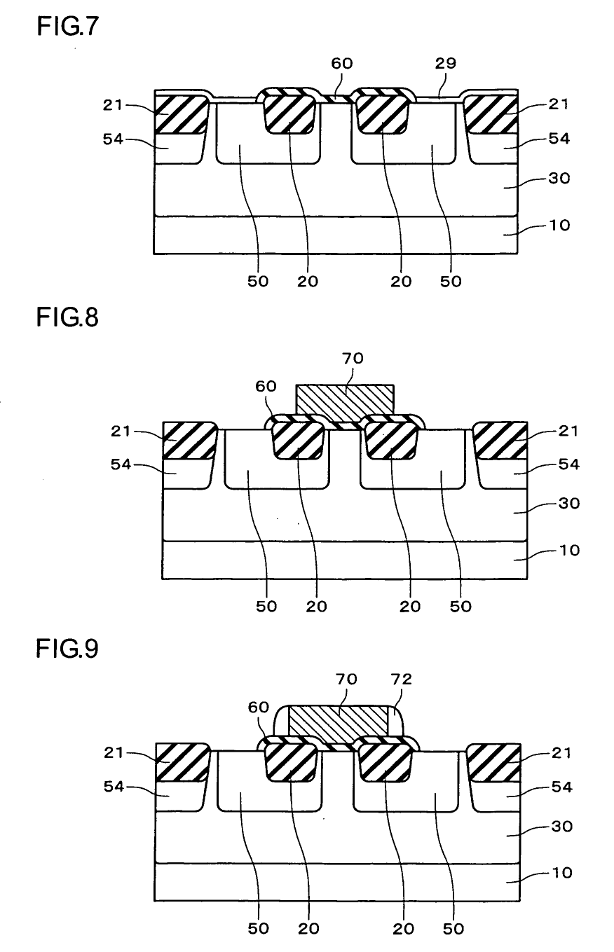

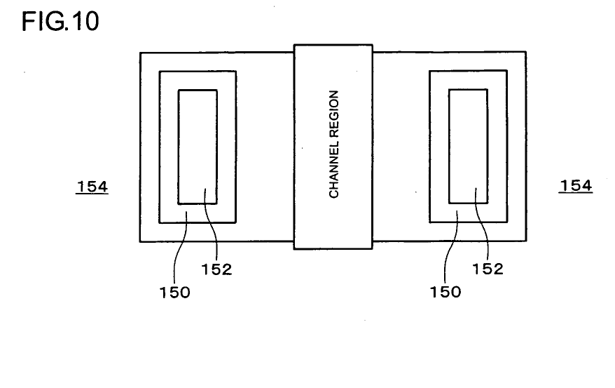

(5) Next, as shown in FIG. 7, a protective film 29 is formed so as to cover at least a region excluding the region where the gate insulation layer 60 of the P channel high voltage transistor 100P is formed. As the protective film 29, for example, the silicon nitride film can be used. In the formation of the protective film 29, firstly, the silicon nitride layer (not shown) is formed on the entire surface of the semiconductor substrate 10. Next, a resist layer (not shown) is formed that includes an opening to the region where the gate insulation layer 60 is formed in a later process. The protective film 29 is formed by patterning the silicon nitride layer with the resist layer as a mask.

Next, as shown in FIG. 7, the gate insulation layer 60 of the high voltage transistor 100P is formed. The gate insulation layer 60 can be formed by means of selective thermal oxidation method. Next, the remaining silicon nitride layer 26 is removed. Additionally, in the process, channel doping may be conducted after forming the protective film 29.

(6) Next, as shown in FIG. 8, the gate electrode 70 is formed on the gate insulation layer 60. In the forming of the gate electrode 70, firstly, a conductive layer (not shown) is formed on the entire surface. A resist layer (not shown) having a desired pattern is formed on the conductive layer. Using the resist layer as a mask, the gate electrode 70 is formed by patterning the conductive layer.

(7) Next, as shown in FIG. 9, the sidewall insulation layer 72 is formed to the side surface of the gate electrode 70. In the forming of the sidewall insulation layer 72, firstly, the insulating layer (not shown) is formed on the entire surface. Next, the sidewall insulation layer 72 is formed by conducting an anisotropic etching on the insulating layer.

(8) Then, as referred to FIG. 1, the source/drain region 52 composed of P-type high density doped region is formed by introducing P-type impurities into a desired region.

The semiconductor device of the embodiment can be manufactured by the above-mentioned processes. The method of manufacturing the semiconductor device of the embodiment is not limited to the above-mentioned manufacturing method. Any methods capable for manufacturing the semiconductor device of the invention are applicable. In addition, the forming of the offset region 50 in the process (3) can be conducted simultaneously with the forming of the channel stopper region of the N-channel transistor fabricated on the same substrate. Likewise, the forming of the channel stopper region 54 in the process (4) can be conducted simultaneously with the forming of the offset region of the N-channel transistor fabricated on the same substrate. In the semiconductor device of the embodiment, the channel stopper region 54 includes the protrusion 54a toward the long side of the gate insulation layer 60 so as to make the distance narrow between the channel stopper region 54 and the gate isolation layer 60 (channel region). This makes it possible to assure the withstanding voltage even if the impurity density in the channel stopper region 54 is lowered. As the result, a semiconductor device having high reliability can be manufactured while reducing the number of processes by forming the channel stopper region and offset region in the same process.

In addition, as an example of the method of manufacturing a semiconductor device of the embodiment, it is exemplified the case where the element isolation insulation layer 21 and the offset insulation layer 20 are formed in the same process. However, they may be processed in individual process, not limited to this. Further, while it is exemplified the case where a semi-recessed LOCOS method is employed as the forming method, a LOCOS method or a STI method may be employed.

1. A semiconductor device comprising;
a gate insulation layer formed on a semiconductor layer;
a source and a drain region formed in the semiconductor layer;
an offset region composed of a doped layer of which concentration is low comparing to that of the source region and the drain region and surrounds the source region and the drain region; and
a channel stopper region formed on the outside of the offset region, wherein
the stopper region includes a protrusion such that the distance between the gate insulation layer and the channel stopper region to the long side of the gate insulation layer is narrower than the distance between the offset region and the channel stopper region to the long side of the offset region.

2. The semiconductor device according to claim 1, wherein the protrusion is protruded almost toward the long side of the gate insulation layer.

3. The semiconductor device according to claim 1, wherein the length of the long side of the region in which the gate insulation layer is formed, is almost equal to the length of the long side of the source region and the drain region.

4. The semiconductor device according to claim 2, wherein the length of the long side of the region in which the gate insulation layer is formed, is almost equal to the length of the long side of the source region and the drain region.
